(19) United States
(12) Patent Application Publication
(10) Pub. No.: US 2012/0196442 A1
(43) Pub. Date: Aug. 2, 2012

(54) CHEMICAL MECHANICAL POLISHING METHOD

(75) Inventor: WUFENG DENG, Shanghai (CN)

(73) Assignee: Semiconductor Manufacturing International (Shanghai) Corporation, Shanghai (CN)

(21) Appl. No.: 13/244,173

(22) Filed: Sep. 23, 2011

(30) Foreign Application Priority Data
Jan. 31, 2011 (CN) 201110034120.X

(51) Int. Cl. H01L 21/304

(52) U.S. Cl. 438/693; 257/E21.239

(57) ABSTRACT

A chemical mechanical polishing method includes providing a semiconductor substrate having a dielectric layer formed thereon, wherein the dielectric layer includes vias and/or grooves, forming a stop layer on the dielectric layer and on sidewalls and bottoms of the vias and/or grooves; forming a metal layer on the stop layer, which completely fills the vias and/or grooves. The method further includes grinding the metal layer until the stop layer is exposed, removing a portion of the stop layer with a first grinding slurry, and removing the stop layer left over with a second grinding slurry until the dielectric layer is exposed, wherein a quantity and a diameter of oxide grinding particles in the second grinding slurry are smaller than those in the first grinding slurry. The method guarantees a removal rate that is equal to conventional art and prevents damage to the wafer so that the products thus made have an improved quality and performance.

### CROSS-REFERENCES TO RELATED APPLICATIONS

The present application claims the priority of Chinese Patent Application No. 201110034120.X, entitled “CHEMICAL MECHANICAL POLISHING METHOD”, and filed on Jan. 31, 2011, the entire disclosure of which is incorporated herein by reference.

### FIELD OF THE INVENTION

The present invention is generally related to semiconductor technology, and more particularly, to a chemical mechanical polishing method.

### BACKGROUND OF THE INVENTION

With the continuous development of IC manufacturing technology and the integrated level of semiconductor devices, the critical dimension (hereinafter referred as “CD”) of the semiconductor devises is continuously getting smaller. Requirements for metal interconnection structures which connect the semiconductor devices are also continuously getting higher, accompanying with the CD of the semiconductor devices being smaller. In large scale integrated circuits, high electric resistance is likely to induce a jump line phenomenon to electrons, which causes the devices nearby to operate incorrectly. As a result, metal interconnection structures which are made of Al can not meet technical requirements because Al has a relatively high electric resistance. In a conventional manufacturing process of the interconnection structures, Cu replaces Al in the interconnection structures. Cu has a faster and more stable signal transmission speed than Al, therefore, it is more advantageous to use Cu over Al to obtain better chip performance.

When forming Cu lines or Cu conductive plugs by a conventional process, after a metal layer is formed, a chemical mechanical polishing (hereinafter referred as “CMP”) process is performed to the metal layer for planarization. However, during the planarization process, the conventional CMP process may generally create scratches on a surface of a wafer, which impacts the product yield. The scratches may be divided into micro-scratches and macro-scratches according to damage levels thereof. Micro-scratches on the wafer surface are mainly due to frictions between the wafer surface and micro-particles during a grinding process. The micro-particles are mainly from a gathering of grinding particles in a grinding slurry and from pollutions caused by a polishing machine or outer environment during the grinding process. Those skilled in the art may understand that, the grinding slurry generally includes chemical assistants and oxide grinding particles, wherein the chemical assistants may be oxidizing agents, surfactants, pH buffering agents, etc, and the oxide grinding particles may be silica, bauxite, etc. Generally, a removal rate of the grinding process to the wafer is higher when there are more and larger oxide grinding particles in the grinding slurry. However, because the oxide grinding particles are larger, a possibility of causing damage on the wafer surface by the oxide grinding particles is higher. Conversely, when there are fewer and smaller oxide grinding particles in the grinding slurry, the removal rate the grinding process to the wafer surface is lower, which may impact the process rate. Nevertheless, because the oxide grinding particles are relatively small, damage caused on the wafer surface by the oxide grinding particles are also relatively small.

A CMP method provided in the prior art adds deionized water to a grinding pad in the second half of the CMP process in order to improve the grinding effect caused by using a grinding slurry with a high selectivity, which reduces the micro-scratches on the wafer surface. However, the deionized water is added in the second half of the CMP process, therefore, although the removal rate may be raised and the micro-scratches on the wafer surface may be reduced to some extent, damage to the wafer surface caused by the oxide grinding particles in the grinding slurry may not be prevented. Therefore, if a technical solution is provided by improving the grinding slurry in which both the removal rate and the wafer damage may be taken into account, the whole CMP process may be improved. However, the prior art fails to provide any effective solutions.

### BRIEF SUMMARY OF THE INVENTION

Embodiments of the present invention provide a CMP method which may prevent micro-scratches from being formed on a wafer surface.

According to an embodiment of the present invention, a CMP method includes providing a semiconductor substrate having a dielectric layer formed thereon, wherein the dielectric layer includes vias and/or grooves; forming a stop layer on the dielectric layer and on sidewalls and bottoms of the vias and/or grooves; forming a metal layer on the stop layer, wherein the metal layer completely fills the vias and/or grooves. The method further includes grinding the metal layer until the stop layer is exposed; removing a portion of the stop layer with a first grinding slurry to reduce a thickness thereof; and removing the stop layer left over with a second grinding slurry until the dielectric layer is exposed, wherein a quantity and a diameter of oxide grinding particles contained in the second grinding slurry are smaller than a quantity and diameter of oxide grinding particles contained in the first grinding slurry.

Optionally, the first grinding slurry may be an oxide slurry comprising water, chemical assistants and oxide grinding particles, wherein a weight percentage of the oxide grinding particles in the first grinding slurry is greater than 8%.

Optionally, the diameter of the oxide grinding particles in the first grinding slurry is more than 50 nm.

Optionally, the second grinding slurry may be an oxide slurry comprising water, chemical assistants and oxide grinding particles, wherein a weight percentage of the oxide grinding particles in the second grinding slurry is less than 8%.

Optionally, the diameter of the oxide grinding particles in the second grinding slurry ranges from about 10 nm to about 50 nm.

Optionally, the oxide slurry comprises a KOH solution or an ammonium hydroxide solution.

Optionally, a pH value of the first grinding slurry is the same as a pH value of the second grinding slurry.

Optionally, the stop layer may include a material selected from a group consisting of tantalum, tantalum oxide, and tantalum silicon nitrogen.

Optionally, the thickness of the stop layer being removed by the first grinding slurry ranges from about 80% to about 90% of the thickness of the entire stop layer.

Optionally, the method further includes cleaning a grinding pad before applying the second grinding slurry to grind the remaining stop layer until the dielectric layer is exposed.

Optionally, the cleaning process on the grinding pad lasts more than 10 seconds.

Embodiments of the present invention provide a CMP method that has the following features and advantages. According to an embodiment, two successive CMP processes are performed on the wafer, each CMP process uses a different type of grinding slurries. Specifically, after grinding the metal layer until the stop layer is exposed, the first grinding slurry which includes more and larger oxide grinding particles is applied to grind the stop layer. The first CMP process may remove a great portion of the stop layer; then, the second grinding slurry which includes fewer and smaller oxide grinding particles is applied to grind the remaining stop layer until the dielectric layer is exposed. Further, before applying the second grinding slurry, the grinding pad is first cleaned to remove the oxide grinding particles of the first grinding slurry left over thereon, which prevents abrading a wafer surface caused by the oxide grinding particles of the first grinding slurry. By applying the CMP method described above, the removal rate of the wafer can be maintained, and the damage of the wafer surface caused by the oxide grinding particles of the grinding slurry can be avoided, thereby improving the quality and performance of final products.

Further, in another embodiment of the present invention, a weight percentage of the oxide grinding particles in the first grinding slurry is greater than 8%, the diameter of the oxide grinding particles in the first grinding slurry is more than 50 nm, a weight percentage of the oxide grinding particles in the second grinding slurry is less than 8%, and the diameter of the oxide grinding particles in the second grinding slurry ranges from about 10 nm to about 50 nm. By applying the two grinding slurries, the removal rate of the wafer can be maintained, and the damage of the wafer surface caused by the oxide grinding particles of the grinding slurry can be prevented.

### BRIEF DESCRIPTION OF THE DRAWINGS

FIG. 1 is a flow chart of a CMP method according to an embodiment of the present invention;

FIGS. 2 to 6 are schematic cross-sectional views of intermediate structures illustrating a CMP method performed in a metal wiring process according to an embodiment of the present invention; and

FIGS. 7 to 10 are schematic cross-sectional views of intermediate structures illustrating a CMP method performed in a process for forming a dual damascene structure according to an embodiment of the present invention.

### DETAILED DESCRIPTION OF THE INVENTION

Inventors of the present invention found that a grinding slurry applied in a conventional chemical mechanical polishing (CMP) process may not meet the requirements of both maintaining a relatively high removal rate and reducing wafer surface damage caused by grinding particles in the grinding slurry. That is because, in a grinding process, generally, when the grinding slurry includes more grinding particles and the grinding particles are larger, the removal rate of the wafer may be higher. However, as a result of the bigger grinding particles, the possibility of causing damage to the wafer surface may be higher. Conversely, when the grinding slurry includes fewer grinding particles and the grinding particles are smaller, the removal rate of the wafer may be lower, which decreases the rate or speed of the CPM process. However, because the grinding particles are relatively smaller, the potential to cause damage to the wafer surface may be relatively lower.

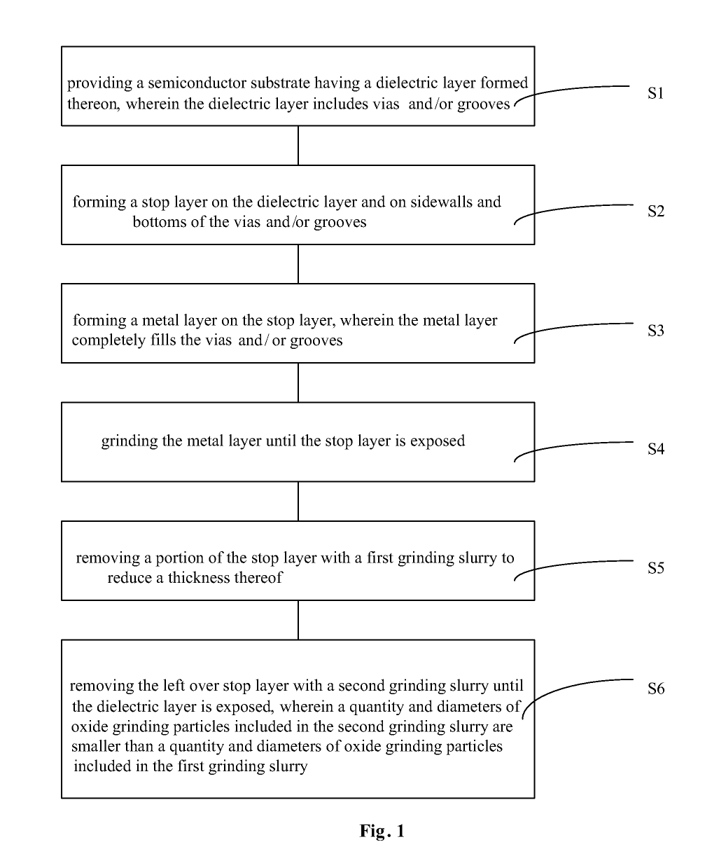

In order to resolve the problems mentioned above, an embodiment of the present invention provides a flow chart of process steps of a CMP method, as shown in FIG. 1. The method includes: S1, providing a semiconductor substrate having a dielectric layer formed thereon, wherein the dielectric layer includes vias and/or grooves; S2, forming a stop layer on the dielectric layer and on sidewalls and bottoms of the vias and/or grooves; S3, forming a metal layer on the stop layer, wherein the metal layer fills the vias and/or grooves completely; S4, grinding the metal layer until the stop layer is exposed; S5, removing a portion of the stop layer with a first grinding slurry to reduce a thickness thereof; and S6, removing the stop layer left over with a second grinding slurry until the dielectric layer is exposed, wherein a quantity and a diameter of oxide grinding particles contained in the second grinding slurry are smaller than a quantity and a diameter of oxide grinding particles contained in the first grinding slurry.

By applying the CMP method described above, the removal rate of the wafer can be maintained, and the damage of the wafer surface caused by the oxide grinding particles of the grinding slurry can be prevented, thereby improving the quality and performance of final products.

The features, characteristics and advantages of the present invention will become apparent from the following description in conjunction with the accompanying drawings.

### Embodiment One

By taking a metal wiring process as an example, an embodiment of the present invention may be described in detail in conjunction with the accompanying drawings. FIG. 1 is a flow chart of a CMP method according to an embodiment of the present invention.

FIGS. 2 to 6 are schematic cross-sectional views of intermediate structures illustrating a CMP method performed in the metal wiring process according to embodiments of the present invention.

First, as shown in FIG. 2, a semiconductor substrate (not shown in the figures) is provided. Semiconductor devices such as transistors, capacitors, and the like, are formed on the semiconductor substrate. A dielectric layer 13 is formed on the semiconductor substrate. The dielectric layer 13 may include a material selected from a group consisting of silicon oxide, silicon oxynitride, and the like.

Referring to FIG. 2, grooves 14 are formed in the dielectric layer 13 through an etching process. The grooves may be connected with other semiconductor devices by conductive plugs in the dielectric layer. A stop layer 12 is formed on the dielectric layer 13 and on sidewalls and bottoms of the grooves by applying a deposition process. The stop layer 12 may include a material selected form a group consisting of tantalum, tantalum oxide and tantalum silicon nitrogen. The stop layer 12 is used to prevent a metal layer which is filled into the grooves in subsequent processes from diffusing into the dielectric layer 13.

Referring to FIG. 2, a metal layer 11 is formed on the stop layer 12 and completely fills the grooves.

In an embodiment, the metal layer 11 is Cu and can be deposited by an electrochemical vapor deposition (EVD) process.

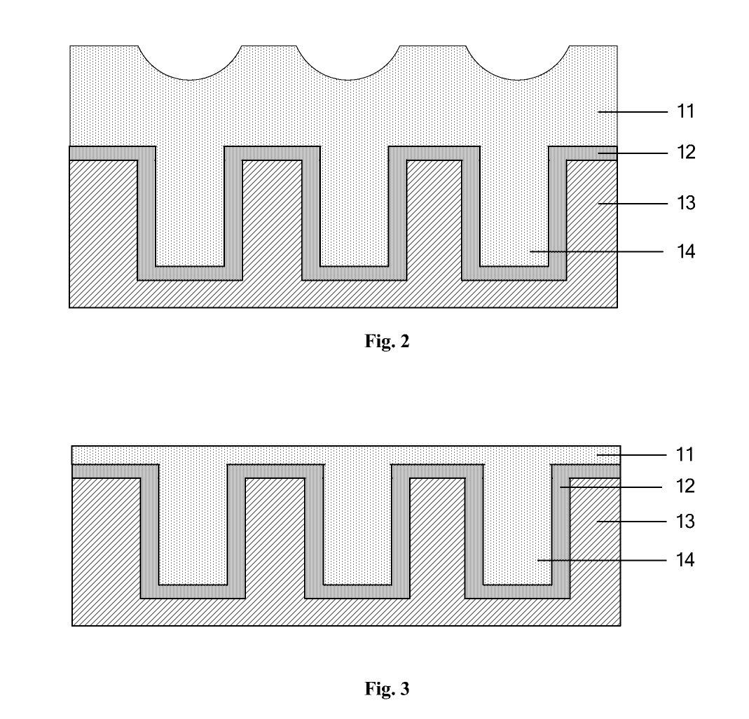

Referring to step S4 in FIG. 1, the metal layer 11 is grinded until the stop layer 12 is exposed. This grinding process includes two grinding processes: a first grinding process and a second grinding process. First, as shown in FIG. 3, in the first grinding process, the metal layer 11 on the stop layer 12 is grinded to remove a major portion of the metal layer 11. Because the first grinding process is a rough grinding process, the removal rate thereof is relatively high. However, a desired planarization effect of the metal layer 11 may not be accomplished. Therefore, the second grinding process is performed to the remaining metal layer 11, so as to achieve the desired planarization effect. In an embodiment, the thickness of the major portion of the metal layer that is reduced by the first grinding process may be about 90% of the total thickness of the metal layer 11 which needs to be removed. A grinding slurry used herein includes a relatively large quantity of grinding particles. Moreover, a rotation speed of a grinding pad and/or head is relatively high, and a pressure of the grinding head to the wafer is relatively high. Thus, a fast grinding rate may be accomplished.

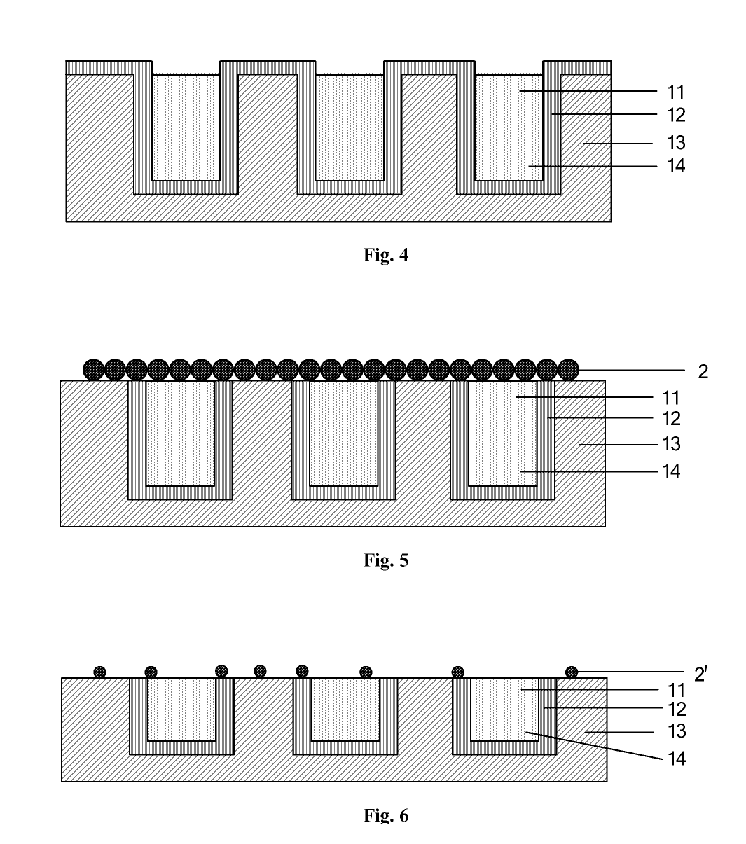

Thereafter, as shown in FIG. 4, the remaining metal layer 11 on the stop layer 12 is grinded until the stop layer 12 is exposed using the second grinding process. Specifically, the second grinding process is a fine grinding process. A grinding slurry used herein generally include a relatively small quantity of grinding particles. Besides, the rotation speed of the grinding pad and/or head is relatively low, and the pressure of the grinding head to the wafer is relatively small. Thus, a desired planarization effect to the metal layer 11 may be accomplished.

Referring to FIG. 5 and step S5 in FIG. 1, a first grinding slurry is applied to remove a portion of the stop layer 12 to reduce a thickness thereof.

In an embodiment, the first slurry includes some oxide grinding particles 2. Optionally, the first grinding slurry is an oxide slurry, including water, chemical assistants, oxide grinding particles, and the like, wherein a weight percentage of the oxide grinding particles 2 in the first grinding slurry is greater than 8%, and the diameters of the oxide grinding particles 2 are more than 50 nm. Specifically, during the grinding process, a surface of the stop layer 12 is oxidized by chemical assistants so as to form an oxide thin film layer which is likely to be removed. Then, the oxide thin film layer is removed by the oxide grinding particles 2 in the first grinding slurry. Immediately, a new surface of the stop layer 12 is oxidized by the chemical assistants so as to form a new oxide thin film layer which is removed by the oxide grinding particles 2. The chemical mechanical polishing on the stop layer 12 repeats in this way until a majority of the stop layer 12 is removed.

Further, because the quantity and diameters of the oxide grinding particles 2 in the first grinding slurry are relatively larger, the majority of the stop layer 12 to be grinded is likely to be removed quickly by using the first grinding slurry. In practice, after being grinded by the first grinding slurry, the thickness of the stop layer removed by the first grinding slurry ranges from about 80% to about 90% of the whole thickness of the stop layer.

Referring to FIG. 6 and the step S6 in FIG. 1, the remaining stop layer 12 is grinded with a second grinding slurry until the dielectric layer 13 is exposed.

In an embodiment, the second grinding slurry includes some oxide grinding particles 2′. Optionally, the second grinding slurry is an oxide slurry which includes water, chemical assistants, oxide grinding particles, and the like. Diameters of the oxide grinding particles 2′ in the second grinding slurry is less than the diameters of the oxide grinding particles 2 in the first grinding slurry. A quantity of the oxide grinding particles 2′ in the second grinding slurry is also less than the quantity of the oxide grinding particles 2 in the first grinding slurry. Specifically, a weight percentage of the oxide grinding particles 2′ in the second grinding slurry is less than 8%, and the diameter of the oxide grinding particles 2′ ranges from about 10 nm to about 50 nm. Similar to the first grinding slurry, the second grinding slurry also includes chemical assistants. During the grinding process by the second grinding slurry, a surface of the stop layer 12 or the metal layer 11 is oxidized by the chemical assistants so as to form an oxide thin film layer which is likely to be removed. Then the oxide thin film layer is removed by the oxide grinding particles 2′ in the second grinding slurry.

Those skilled in the art may understand that, because the diameter and quantity of the oxide grinding particles 2′ are relatively small, a slow removal rate may be obtained when using the second grinding slurry. Nevertheless, a thickness of the remaining stop layer 12 to be grinded is relatively small, so the whole grinding process may not be severely impacted. And because the diameter and quantity of the oxide grinding particles 2′ are relatively small, a damage degree caused by the oxide grinding particles to the wafer surface may also be relatively small, so that a more desired quality and performance of the final products may be obtained.

It should be noted that the weight percentages of the oxide grinding particles 2 and the oxide grinding particles 2′ in the grinding slurries and the diameters thereof are not limited by the parameters mentioned above. In practice, it is only required that the diameters and quantity of the oxide grinding particles 2′ are smaller than the diameters and quantity of the oxide grinding particles 2. It shall be appreciated by those skilled in the art that alternative ways according to different grinding requirements may be performed without deviating from the scope of the invention. Therefore the invention is not limited within the parameters described here.

It should be further noted that, optionally, in the embodiment, the first and second oxide grinding slurries may be a KOH solution or an ammonium hydroxide solution. And a pH value of the first grinding slurry is the same as or close to a pH value of the second grinding slurry. In an example embodiment, the first and second grinding slurries are alkaline grinding slurries with a pH value ranging from about 9 to about 11. Those skilled in the art may choose a grinding slurry with a suitable pH value to perform the CMP process according to applications.

In another embodiment, a step may be added between the step S5 and step S6: cleaning the grinding pad. According to the first embodiment, because the oxide grinding particles 2 contained in the first grinding slurry have relatively large diameters, the oxide grinding particles 2 being left over on the grinding pad may impact the subsequent grinding effect. Therefore, the cleaning process to the grinding pad is performed before the second grinding slurry is applied. The cleaning process is mainly adapted for removing the oxide grinding particles of the first grinding slurry left over on the grinding pad completely and preventing the wafer surface from being abraded, so that the grinding effect of the subsequent grinding process may be guaranteed.

### Embodiment Two

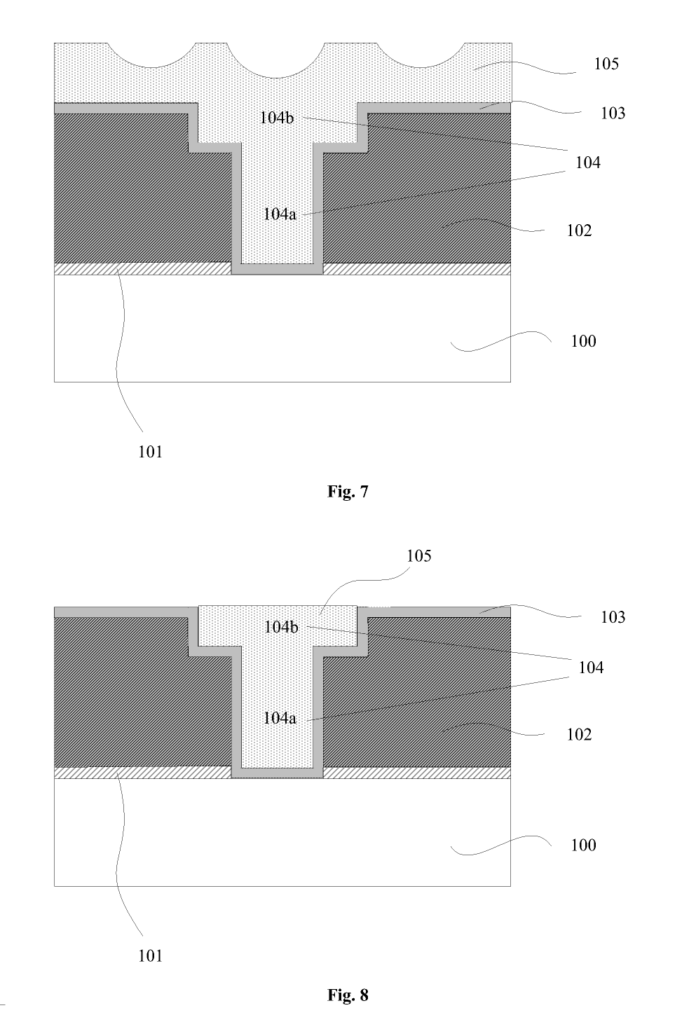

FIGS. 7 to 10 are schematic cross-sectional views of intermediate structures illustrating a CMP method performed in a process for forming a dual damascene structure according to an embodiment of the present invention.

First, as shown in FIG. 7, a semiconductor substrate with metal lines (not shown in the figures) formed therein is provided. A covering layer 101 is formed on the semiconductor substrate 100. A dielectric layer 102 is formed on the covering layer 101. The dielectric layer 102 may comprise a material selected from a group consisting of SiO₂, low-K materials, and the like. Because of the covering layer 101, the metal lines in the semiconductor substrate 100 may be prevented from diffusing into the dielectric layer 102, and also may be protected from being etched in an etching process.

Thereafter, a dual damascene structure 104 is formed by etching the dielectric layer 102 as follows: first, etching the dielectric layer 102 until the metal lines are exposed, so as to form a via 104a; forming a photoresist layer (not shown in the figures) on the dielectric layer 102 and in the via 104a, which defines a pattern of a groove by a development process; and etching the dielectric layer 102 according to the groove pattern by using the photoresist layer as a mask so as to form a groove 104b connected with the via 104a, wherein the via 104a and the groove 104b constitute the dual damascene structure 104.

Then, referring to FIG. 7, a stop layer 103 is formed on the dielectric layer 102 and on sidewalls and bottoms of the dual damascene structure 104. The stop layer 103 may comprise a material selected from a group consisting of tantalum, tantalum oxide, tantalum silicon nitrogen, and the like. The stop layer 103 is formed mainly for prevent a metal layer 105 and the dielectric layer 102 from diffusing into each other, which impacts the performance of the final products. Then, the metal layer 105 is deposited on the stop layer 103. Optionally, the metal layer 105 comprises Cu which is filled into the dual damascene structure 104 by an electrochemical vapor deposition (EVD) process.

Then, referring to FIG. 8, an additional portion of the Cu is removed by a CMP process. In practice, the grinding process of the metal layer 105 may be divided into two steps which may be referred to the step S4 in the Embodiment One and may not be illustrated specifically here.

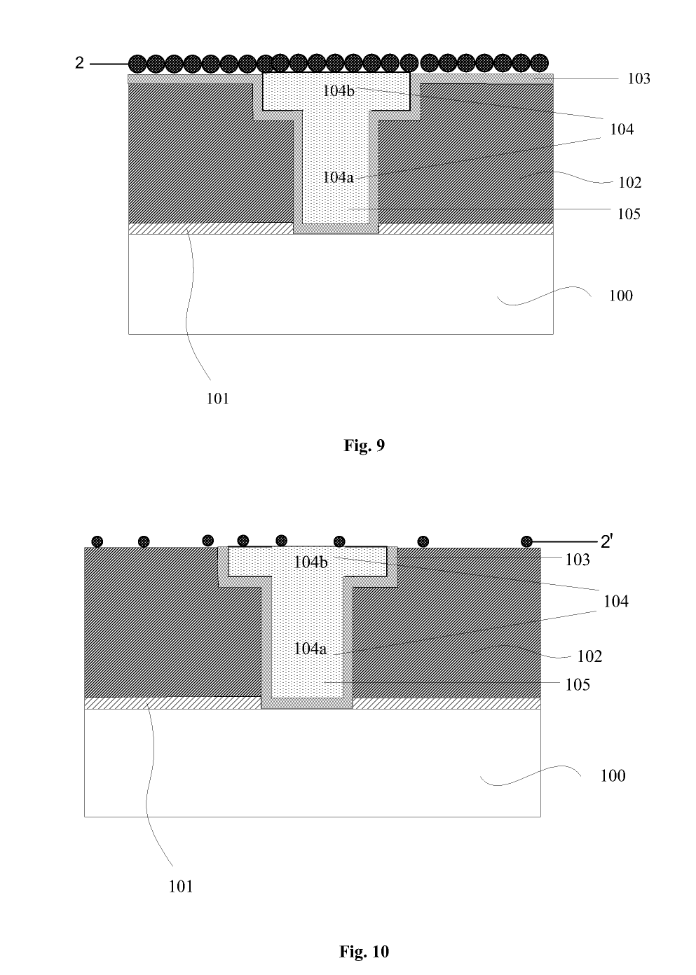

Further, a first grinding slurry is applied to remove a portion of the stop layer 103 to reduce a thickness thereof. As shown in FIG. 9, the first grinding slurry includes some oxide grinding particles 2. Optionally, in the embodiment, the first grinding slurry is an oxide slurry which includes at least water, chemical assistants and oxide grinding particles, wherein a weight percentage of the oxide grinding particles 2 in the first grinding slurry is greater than 8%, and the diameter of the oxide grinding particles 2 is more than 50 nm. Specifically, during the grinding process, a surface of the stop layer 103 is oxidized by the chemical assistants so as to form an oxide thin film layer which is likely to be removed. Then, the oxide thin film layer is removed by the oxide grinding particles 2 in the first grinding slurry. Immediately, a new surface of the stop layer 103 is oxidized by the chemical assistants so as to form a new oxide thin film layer which is removed by the oxide grinding particles 2 then. The chemical mechanical polishing on the stop layer 12 repeats in this way until a major portion of the stop layer 12 is removed.

Because the quantity and the diameter of the oxide grinding particles 2 in the first grinding slurry are relatively large, the portion of the stop layer 103 to be grinded is likely to be removed quickly by using the first grinding slurry. In an embodiment, the thickness of the stop layer being removed by the first grinding slurry ranges from about 80% to about 90% of the entire thickness of the stop layer.

Then, a second grinding slurry is applied to grind the remaining stop layer until the dielectric layer is exposed. As shown in FIG. 10, the second grinding slurry includes oxide grinding particles 2′. Optionally, the second grinding slurry is an oxide slurry comprising at least water, chemical assistants and oxide grinding particles. The oxide grinding particles 2′ in the second grinding slurry has a diameter that is smaller than the diameter of the oxide grinding particles 2 in the first grinding slurry. A quantity of the oxide grinding particles 2′ in the second grinding slurry is also smaller than the quantity of the oxide grinding particles 2 in the first grinding slurry. Specifically, a weight percentage of the oxide grinding particles 2′ in the second grinding slurry is less than 8%, and the diameters of the oxide grinding particles 2′ are ranged from about 10 nm to about 50 nm. Similar to the first grinding slurry, the second grinding slurry also includes chemical assistants. During the grinding process by the second grinding slurry, a surface of the stop layer 103 or the metal layer 105 is oxidized by the chemical assistants so as to form an oxide thin film layer which is likely to be removed. Then the oxide thin film layer is removed by the oxide grinding particles 2′ in the second grinding slurry until the dielectric layer 102 is exposed.

Because the diameter and the quantity of the oxide grinding particles 2′ are relatively small, a slow removal rate may be obtained when using the second grinding slurry. Nevertheless, a thickness of the stop layer 103 left over to be grinded is relatively small, so the whole grinding process may not be impacted greatly. And because the diameters and quantity of the oxide grinding particles 2′ are relatively small, a damage degree caused by the oxide grinding particles to the wafer surface is also relatively small, so that a more desired quality and performance of the final products may be obtained.

It should be noted that the weight percentages of the oxide grinding particles 2 and the oxide grinding particles 2′ in the grinding slurries and the diameters thereof are not limited by the parameters mentioned above in the embodiment. In practice, it is only required that the diameters and quantity of the oxide grinding particles 2′ are smaller than the diameters and quantity of the oxide grinding particles 2. It shall be appreciated by those skilled in the art that alternative ways according to different grinding requirements may be made without deviating from the scope of the invention. Therefore, the invention is not limited to the parameters described herein.

It should be further noted that, optionally, in the embodiment, the first and second oxide grinding slurries may be a KOH solution or an ammonium hydroxide solution. And a pH value of the first grinding slurry is the same as or close to a pH value of the second grinding slurry. For example, optionally, the first and second grinding slurries are alkaline grinding slurries with a pH value ranging from about 9 to about 11. Those skilled in the art may choose a grinding slurry with a suitable pH value to perform the CMP process according to practical requirements.

It should be noted that Embodiment One and Embodiment Two take examples of forming the metal lines structure and forming the dual damascene structure for illustrating the CMP method provided by the embodiments of the present invention, respectively. In practice, the CMP method provided by the embodiments of the present invention may also be applied for grinding other wafer structures, such as a shallow trench isolation (STI), an inter-layer dielectric (ILD) layer, and the like.

The invention is disclosed, but not limited, by preferred embodiment as above. Based on the disclosure of the invention, those skilled in the art can make any variation and modification without departing from the scope of the invention. Therefore, any simple modification, variation and polishing based on the embodiments described herein is within the scope of the present invention.

What is claimed is:

1. A chemical mechanical polishing (CMP) method, comprising:
providing a semiconductor substrate having a dielectric layer formed thereon, wherein the dielectric layer comprises vias and/or grooves;
forming a stop layer on the dielectric layer and on sidewalls and bottoms of the vias and/or grooves;
forming a metal layer on the stop layer, wherein the metal layer completely fills the vias and/or grooves;
grinding the metal layer until the stop layer is exposed;
removing a portion of the stop layer with a first grinding slurry to reduce a thickness thereof; and
removing the stop layer being left over with a second grinding slurry until the dielectric layer is exposed, wherein a quantity and a diameter of oxide grinding particles contained in the second grinding slurry are smaller than a quantity and diameters of oxide grinding particles contained in the first grinding slurry.

2. The CMP method according to claim 1, wherein the first grinding slurry is an oxide slurry comprising water, chemical assistants, and oxide grinding particles, wherein a weight percentage of the oxide grinding particles in the first grinding slurry is greater than 8%.

3. The CMP method according to claim 2, wherein the diameter of the oxide grinding particles in the first grinding slurry is greater than 50 nm.

4. The CMP method according to claim 1, wherein the second grinding slurry is an oxide slurry comprising water, chemical assistants, and oxide grinding particles, wherein a weight percentage of the oxide grinding particles in the second grinding slurry is less than 8%.

5. The CMP method according to claim 4, wherein the diameter of the oxide grinding particles in the second grinding slurry ranges from about 10 nm to about 50 nm.

6. The CMP method according to claim 2, wherein the oxide slurry is a KOH solution or an ammonium hydroxide solution.

7. The CMP method according to claim 1, wherein a pH value of the first grinding slurry is the same as a pH value of the second grinding slurry.

8. The CMP method according to claim 1, wherein the stop layer comprises a material selected from a group consisting of tantalum, tantalum oxide, and tantalum silicon nitrogen.

9. The CMP method according to claim 1, wherein the stop layer being removed by the first grinding slurry has a thickness ranging from about 80% to about 90% of an entire thickness of the stop layer.

10. The CMP method according to claim 1 further comprising cleaning a grinding pad before applying the second grinding slurry to grind the stop layer being left over until the dielectric layer is exposed.

11. The CMP method according to claim 10, wherein the cleaning process on the grinding pad comprises a time duration of more than 10 seconds.

12. The CMP method according to claim 4, wherein the oxide slurry is a KOH solution or an ammonium hydroxide solution.
